(19) United States
(12) Patent Application Publication
(10) Pub. No.: US 2026/0101446 A1
(43) Pub. Date: Apr. 9, 2026

(54) DISPENSING HEATER AND METHODS OF USE

(71) Applicant: NANO DIMENSION TECHNOLOGIES, LTD., Ness Ziona (IL)

(72) Inventor: Daniel EGGERSCHWILER, Aesch (CH)

(73) Assignee: NANO DIMENSION TECHNOLOGIES, LTD., Ness Ziona (IL)

(21) Appl. No.: 19/119,244

(22) PCT Filed: Nov. 16, 2024
(86) PCT No.: PCT/US2024/056309

§ 371 Date: Apr. 8, 2025

Related U.S. Application Data
(60) Provisional application No. 63/703,823, filed on Oct. 4, 2024.

(51) Int. Cl. H05K 3/30; H01L 21/67; H01L 23/00

(52) U.S. Cl. CPC H05K 3/305; H10P 72/0434; H10P 72/0602; H05K 2203/081; H05K 2203/111; H05K 2203/163; H10W 72/01365; H10W 72/07125; H10W 72/07141; H10W 72/07173; H10W 72/07183; H10W 72/07311

(57) ABSTRACT

The disclosure relates to assemblies and methods for preheating objects in the process of underfill. Specifically, the disclosure relates to assemblies and methods for treating printed circuit boards (PCBs), integrated circuits (ICs) wafers and the like, in the preheating stage of the underfill process using an assembly operable to create a customizable hot-air bath with adjustable depth to account for surface topology and necessary clearances, for soaking the PCBs, ICs, wafers and the like in hot air, bringing these to operating temperature.

### BACKGROUND

The disclosure is directed to systems (assemblies) and methods for heating objects in electronics assembly's dispensing processes such as, for example; underfill, and package stacking for Package-on-Package (PoP). Specifically, the disclosure is directed to assemblies and methods for heating printed circuit boards (PCBs), integrated circuits (ICs), advanced packaging (AP), wafers and the like, in material dispensing processes, using an assembly operable to create a customizable hot-air bath accounting for surface topology, for soaking the PCBs, ICs, APs, wafers and the like.

Underfill material, typically in liquid, paste, or gel form, is dispensed in the gap or “underfill” region between the ball grid array BGA/IC component and the PCB after the component has been soldered onto the PCB. Once applied, the underfill material is cured or solidified, forming a strong and durable bond between the component and the PCB. This serves several important purposes. When applied to wafers, SMTs, and PCBs, underfill processing is used to improve the reliability and longevity of electronic assemblies by addressing mainly the mechanical and thermal challenges associated with the mounting of components onto PCBs. The pre-heating phase of the underfill process, is configured to rapidly elevate the temperature of a product from its initial ambient state to the desired PCB temperature before applying the underfill process.

In the context of the disclosure, the term “underfill” refers to a specialized material and process used to enhance the reliability and mechanical stability of integrated circuits (ICs) or electronic components mounted onto PCBs. Underfill is typically used when there is a significant difference in the coefficient of thermal expansion (CTE) between the IC or component (SMT) and the PCB.

PoP stacks typically comprise a bottom package containing an integrated circuit component (e.g., a high-performance logic device), configured to receive a mating top package (e.g., high capacity or combination memory devices). These two components are typically sourced (e.g., due to costs, logistics) from different IC device suppliers, then stacked during the board assembly flow, making the package stacking process challenging because each package may exhibit a different warpage trend from room temperature to reflow temperature, as well as different CTE.

During package-stacking, and because the bottom package has a mold cap, it is necessary to supply flux or paste under the solder ball(s) (or BGA) of the top package(s) in order to modify the surface to connect top and bottom packages while at reflow. Accordingly, the base or bottom packages are transferred (e.g., using pick-and-place systems) to a multiple unit alignment fixture (see e.g., FIG. 2). Next the second-layer package is transferred to, for example, a dip-fluxing station to coat the bottom half of the ball-contact in a uniform fashion. The now-fluxed upper level package(s) are then sequentially placed atop the base packages and the process is repeated for each package layer before a mass reflow soldering step.

The loaded PoP (or portion thereof) is transferred to a forced air/gas convection oven for mass reflow to complete the interlayer solder joining of all package layers. Because of the relatively thin composite of elements within each section of the package, the overall height of the finished Z-Ball Stack package is minimized (ultimately determined by the number of packages joined in the stack).

Various methodologies are available for achieving underfill pre-heating and package stacking mass reflow, the most prevalent approach for underfill process being the deployment of a customized contact vacuum chuck. This specialized fixture is preferred for its ability to facilitate the fastest and uniform heat transfer during the pre-heating process. Although deployment of a customized contact vacuum fixture for preheating PCBs in the context of the underfill process offers advantages like rapid and uniform heat transfer, it also presents several challenges. Customizing and implementing such fixtures can be complex and costly, requiring specialized engineering expertise and resources. Often, being tailored to specific PCB layouts, it lacks versatility, which may necessitate modification for different designs or sizes. Maintenance and calibration are essential to ensure consistent performance over time. Thermal stress on the PCB and components due to direct contact with the fixture must be carefully controlled to prevent warping or damage. Achieving even heat distribution, especially for larger or complex PCBs, can be challenging. While contact fixtures can be fast, loading and unloading PCBs introduces cycle time delays. Compatibility with underfill processes and materials is critical, and integrating custom fixtures into automated production lines may require additional effort. Lastly, scalability to accommodate changing production volumes can be a consideration. Addressing these issues requires meticulous design, maintenance, and monitoring, along with potential exploration of alternative preheating methods or complementary techniques, such as forced air heating or reflow ovens, based on specific production requirements and challenges.

For both the underfill process, as well as for package(s) stacking, several types of infrared heaters can also be used (see e.g., FIG. 1A). Among these are infrared convection ovens, which blend infrared radiation with convection for uniform heating, making them versatile for a range of PCB sizes and geometries. Infrared halogen lamps, on the other hand, emit intense infrared radiation and are particularly useful for localized preheating of specific areas on the PCB, known for their rapid heating capabilities. Infrared panel heaters consist of flat panels emitting infrared radiation, which can be customized to match the shape and size of the PCB, offering uniform heating across its surface.

While infrared heaters offer certain advantages like precise control and energy efficiency, they are not without challenges. One issue is selective heating, where specific components or areas on the PCB may heat up more quickly, potentially leading to uneven temperature distribution and warpage. Likewise, if temperature monitoring and control measures are not diligently followed, overheating may result in damage to components, solder joints, or even the PCB itself. Furthermore, while infrared heaters can be energy-efficient when properly managed, they can consume substantial power if not adequately controlled.

Alternatively, another heating method involves the application of forced hot air. This versatile approach enables the heating of substrates regardless of their geometry or size, without overheating any component nor PCB region; however, the time required to achieve the desired temperature is comparatively longer when compared to contact heating, due to the design requiring the heater to accommodate the largest object to be heated, leading to large unused volume that needs to be heated (See e.g., FIG. 1B). Typically, the process is carried out using a closed chamber with a floor having a grid of holes on the top surface through which the heat is transferred. The method is sometimes scaled out, where several chambers are used, adding complexity and costs to the system.

The disclosed technology addresses some of the foregoing shortcomings.

### SUMMARY

Disclosed, in various exemplary implementations, are assemblies and methods for heating printed circuit boards (PCBs), integrated circuits (ICs), advanced packaging (AP), wafers and the like, in material dispensing processes, using an assembly operable to create a customizable hot-air bath accounting for surface topology, for soaking the PCBs, ICs, APs, wafers and the like.

In an exemplary implementation provided herein is an assembly for heating at least one of: a printed circuit boards (PCBs), an integrated circuits (ICs), an advanced packaging (AP), and a wafer, the assembly comprising: a stage defining a longitudinal axis; a vertically adjustable platform coupled to the stage; and an adjustable quadrilateral frame, in fluid communication with at least one hot gas blower, the adjustable quadrilateral frame operable for selectably adjusting the dimensions of a closed quadrilateral chamber formed by the adjustable quadrilateral frame, the PCB, IC, AP, wafer, and a slab coupled to the vertically adjustable platform.

In another exemplary implementation, provided herein is a method of heating at least one of: a printed circuit boards (PCBs), an integrated circuits (ICs), an advanced packaging (AP), a wafer, and an object comprising one or more of the foregoing sought to be heated in a dispensing process, the method implemented in an assembly comprising: a stage defining a longitudinal axis; a vertically adjustable platform coupled to the stage and configured to receive and engage the at least one of: the PCB, the IC, the AP, the wafer, or an object comprising one or more of the foregoing and an object comprising one or more of the foregoing sought to be heated in a dispensing process; and an adjustable quadrilateral frame, in fluid communication with at least one hot gas blower, the adjustable quadrilateral frame operable for selectably adjusting the dimensions of a closed quadrilateral chamber formed by the adjustable quadrilateral frame, the PCB, IC, AP, wafer, or the object comprising one or more of the foregoing sought to be heated in a dispensing process, and a slab coupled to the vertically adjustable platform, the method comprising: based on the length and width of the at least one of: the PCB, the IC, the AP, the wafer, and the object comprising one or more of the foregoing sought to be heated in a dispensing process-adjusting the dimensions of the adjustable quadrilateral frame; based on at least one of: a thickness, topology, and a clearance requirement of or for the at least one of: the PCB, the IC, the AP, the wafer, and an object comprising one or more of the foregoing sought to be heated in a dispensing process, and using the vertically adjustable platform, raising the at least one of: the PCB, the IC, the AP, the wafer, and the object comprising one or more of the foregoing sought to be heated in a dispensing process such that he at least one of: the PCB, the IC, the AP, the wafer, and the object comprising one or more of the foregoing sought to be heated in a dispensing process forms a lid to the chamber, while a slab coupled to the vertically adjustable platform forms a floor of the closed quadrilateral chamber; actuating the hot gas blower; and using a sensor included with the assembly, continuously monitoring the temperature of the PCB, IC, AP, wafer, or the object comprising one or more of the foregoing sought to be heated in a dispensing process, each coupled to the assembly for a predetermined time at a predetermined temperature range.

In yet another exemplary implementation, the dispensing process is an underfill dispensing process, and/or a package stacking dispensing process.

These and other features of the assemblies and methods for heating the at least one of: the PCB, the IC, the AP, the wafer, and an object comprising one or more of the foregoing sought to be heated in a dispensing process will become better understood in view of the following figures and detailed description.

### BRIEF DESCRIPTION OF THE FIGURES

For a better understanding of the assemblies and methods for heating the at least one of: the PCB, the IC, the AP, the wafer, and an object comprising one or more of the foregoing sought to be heated in a dispensing process, reference is made to the accompanying examples and figures, in which:

FIGS. 1A, 1B, depict prior art heaters;

FIG. 2, is a schematic illustrating an exemplary implementation of the underfill process'assembly;

FIG. 3A, is a schematic illustration of an exemplary implementation of the vertically adjustable platform, with FIGS. 3B-3D, illustrating various Z-axis positioning;

FIG. 4, is a schematic illustrating an exemplary implementation of the adjustable quadrilateral frame;

FIG. 5A, illustrates an exemplary implementation of the hot gas blowers, with FIG. 5B, being a schematic illustrating another exemplary implementation of the hot gas (e.g., air, nitrogen) blowers; and

FIG. 6, illustrating an enlarged portion of FIG. 1.

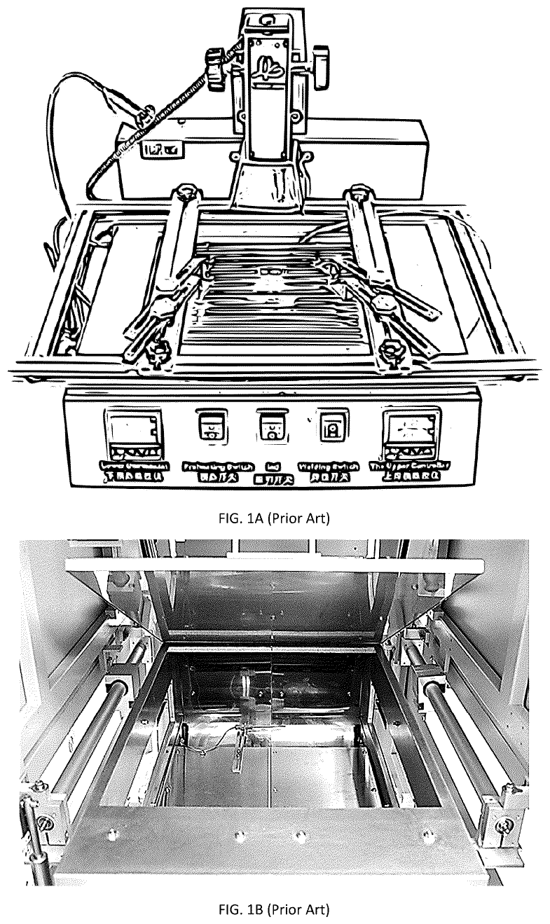

### DETAILED DESCRIPTION

Provided herein are exemplary implementations of assemblies and methods for heating printed circuit boards (PCBs), integrated circuits (ICs), advanced packaging (AP), wafers and the like, in material dispensing processes, using an assembly operable to create a customizable hot-air bath accounting for surface topology, components sensitivity, or other clearance requirements, for soaking the PCBs, ICs, APs, wafers and the like during dispensing processes.

A more complete understanding of the components, processes, assemblies, and devices disclosed herein can be obtained by reference to the accompanying drawings. These figures (also referred to herein as “FIG.”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary implementations. Although specific terms are used in the following description for the sake of clarity, these terms are intended to refer only to the particular structure of the exemplary implementations selected for illustration in the drawings, and are not intended to define or limit the scope of the disclosure. In the drawings and the following description below, it is to be understood that like numeric designations refer to components of like function.

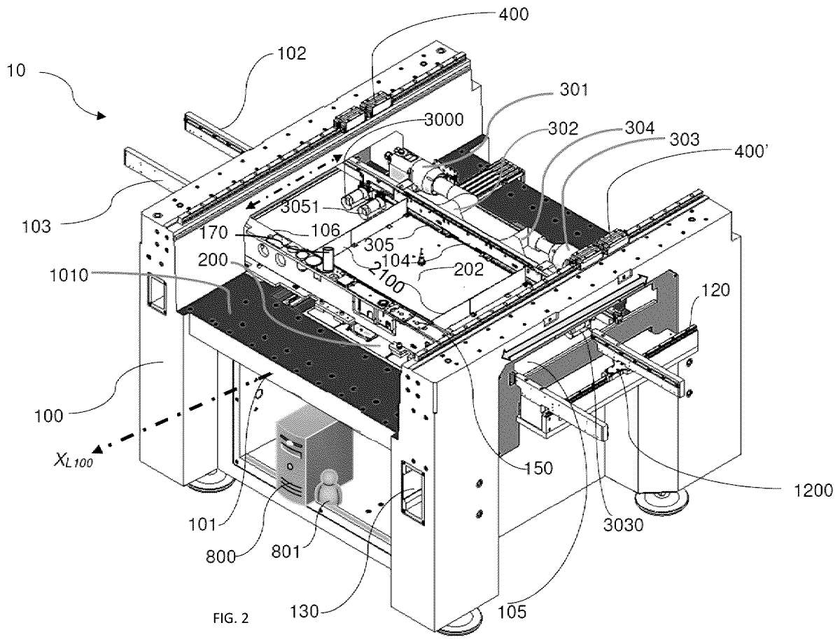

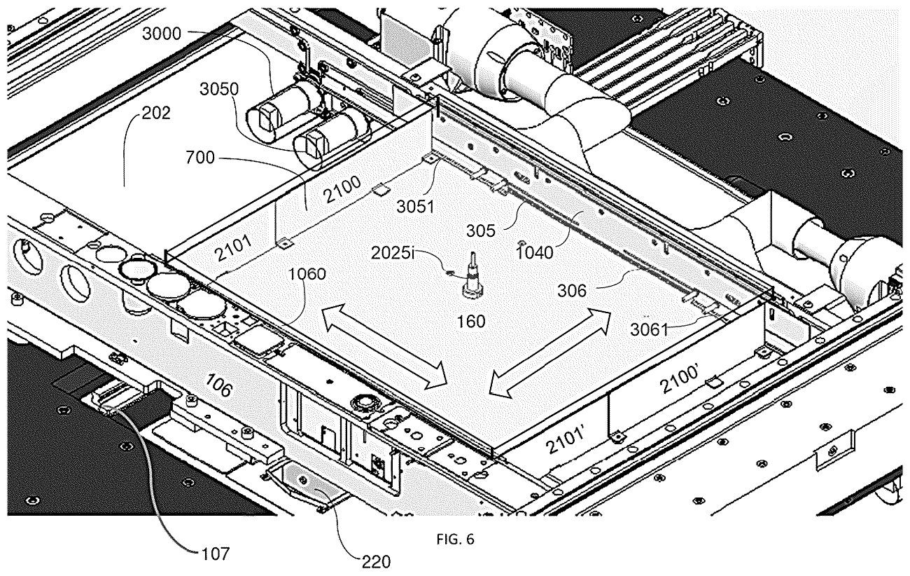

Turning to FIGS. 2-6 illustrating assembly 10 comprising: stage 100 defining longitudinal axis X_{L100}; vertically adjustable platform 200 coupled to stage 100; and adjustable open quadrilateral frame 150, in fluid communication with at least one hot gas blower 301 (303), adjustable quadrilateral frame 150 operable to slectably (in other words, without affecting other components or processes), adjust volume of closed quadrilateral chamber 160 (see e.g., FIG. 6) formed by adjustable quadrilateral frame 150, the at least one of: the PCB, the IC, the AP, the wafer, and an object comprising one or more of the foregoing 700 sought to be heated in the dispensing process, each forming the lid of closed quadrilateral chamber 160, and slab 202 coupled to vertically adjustable platform forming the floor of closed quadrilateral chamber 160. As illustrated in FIGS. 2, and 6, stage 100 further comprises base 1010 providing support for vertically adjustable platform 200. Vertically adjustable platform 200 configured to transition between a default position where slab 202 is flush with stage 100 base 1010, and a raised position where at least one of: PCB, IC, AP, wafer, and object comprising one or more of the foregoing 700 sought to be heated in the dispensing process are framed by open quadrilateral frame 150. Furthermore, stage 100 further defines a pair of openings 105, 105′ with rails 102, 103 disposed transverse to longitudinal axis X_{L100}, rails 102, 103 being movable along (in parallel with) longitudinal axis, providing yaw adjustment for adjustable quadrilateral frame 150, using pair of strips 120, 120′ (not shown) with actuators 1200, 1200′ (not shown). It is noted that stage 100 forms one unit operation in the dispensing process and can be coupled to other unit operations, for example a dip-fluxing station, a pick-and-place station, a second heating station and the like.

In the context of the disclosure, the term “assembly” refers to “a collection of parts so assembled as to form a complete machine, structure, or unit of a machine. An assembly may be a collection of parts to be fitted together to make a whole”.

The term “fluid communication” refers to any area, a structure, or communication that allows for fluid communication between at least two fluid retaining regions, for example, a tube, duct, conduit or the like connecting two regions. One or more fluid communication can be configured or adapted to provide for example, vacuum driven flow, electrokinetic driven flow, control the rate and timing of fluid flow by varying the dimensions of the fluid communication passageway such as slits 305, 306, rate of circulation or a combination comprising one or more of the foregoing. Alternatively, and in another exemplary implementation, the term “in communication” can also refer to gaseous communication, i.e. that gas may be transferred from one volume to another volume since these volumes are in communication. This term does not exclude the presence of a gas shutter, baffles, dampers or valve between the volumes that may be used to interrupt the gas communication between the volumes.

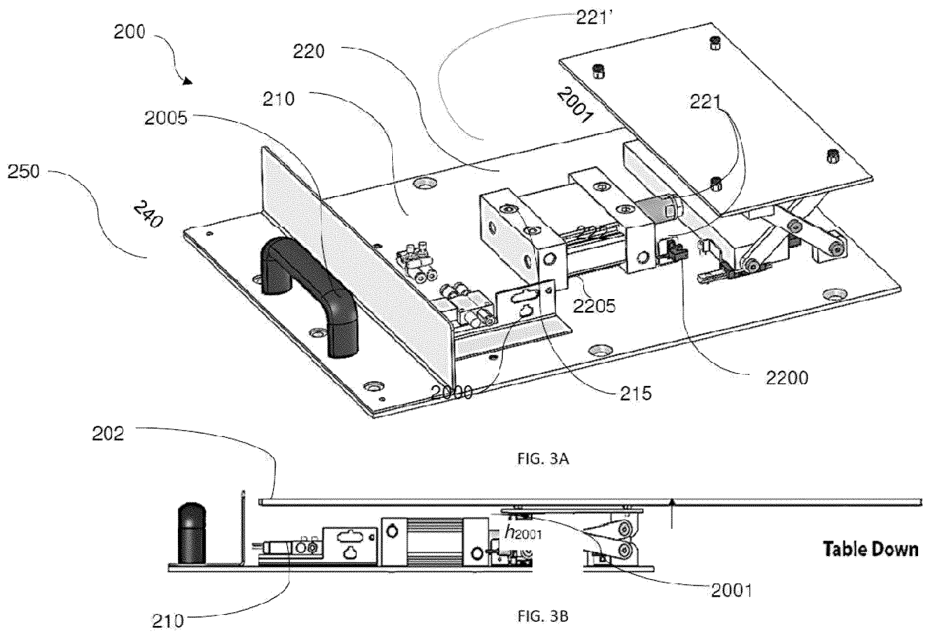

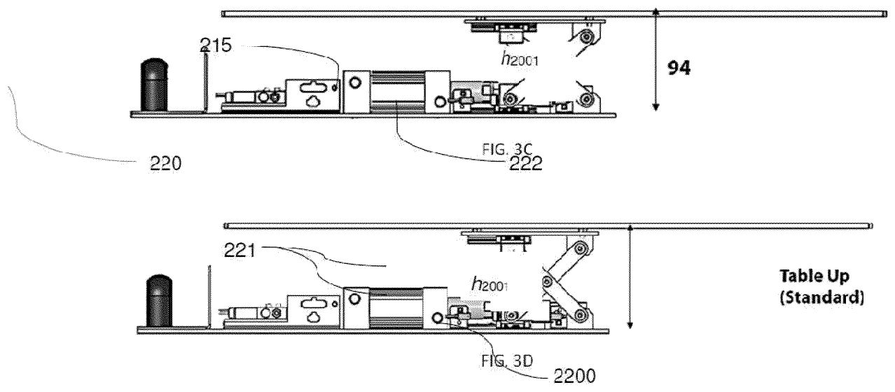

In an exemplary implementation, vertically adjustable platform 200 (see e.g., FIG. 3) used in assembly 10 can comprise: base plate 200 having top surface motor 210, coupled to top surface of base plate 2000, and drivetrain 220 operably coupled to pneumatic valve or any other kind of linear actuator 210, via coupler 215, wherein drivetrain 220 is further coupled to slab 202 via plate 2001. Drivetrain 220 being operable to selectably raise and lower slab (in other words, move plate 2001 along the Z-axis, without affecting other parameters). As further illustrated in FIG. 3, vertically adjustable platform 200 further comprises handle 250, and shield 240. pneumatic valve or any other kind of linear actuator 210 can be coupled to drivetrain 220, via for example coupler 215, which can be a shaft coupling member, for example, universal coupler, Hookes joint, Cardant joint and the like. Furthermore, as illustrated, drivetrain 220 is comprised of stationary anchors 2200, 2200′ (not shown), to which pivotally coupled lift arms 221, 221′ are coupled with movable member 222 operable to slide on rails 2205 toward stationary anchors 2200, 2200′ thereby lifting plate 2001. As indicated, in the default position, upper surface of slab 202 is flush with base 1010 of stage 100, and is operable to receive and engage at least one of: PCB, IC, AP, wafer, and object comprising one or more of the foregoing 700 sought to be heated in the dispensing process, lifting (raising) each, through open quadrilateral frame 150 adjusted to accommodate each of: PCB, IC, AP, wafer, and object comprising one or more of the foregoing 700 sought to be heated in the dispensing process.

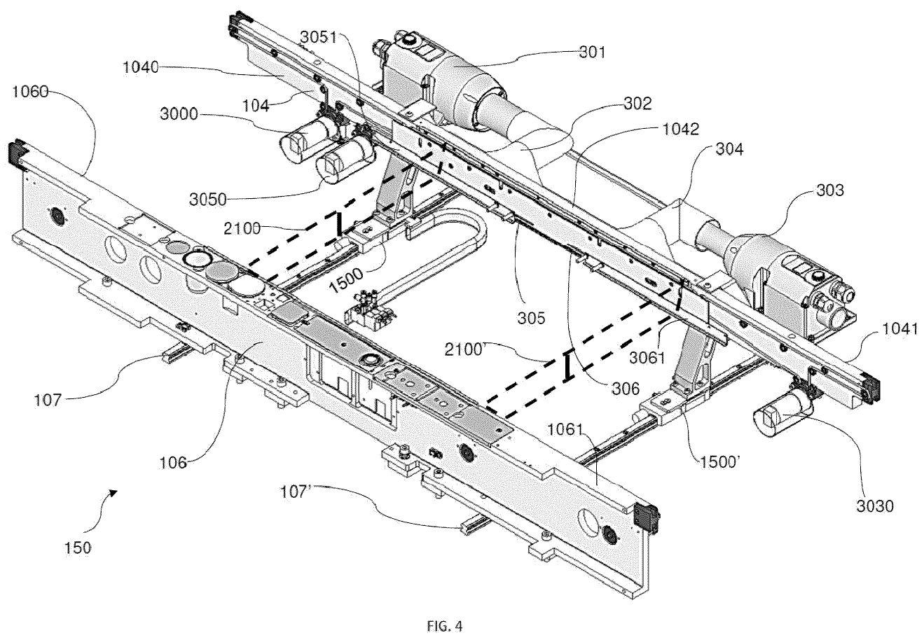

As further illustrated, the adjustable quadrilateral frame 150, used in the assemblies and methods for the at least one of: the PCB, the IC, the AP, the wafer, and an object comprising one or more of the foregoing 700 sought to be heated in the dispensing process disclosed herein, can comprise: movable bar 104 having internal facet 1040 (see e.g., FIG. 4), and external facet 1041 and top facet 1042, disposed transverse to longitudinal axis X_{L100} defined by stage 100. Movable bar 106, is shown disposed in parallel with movable bar 104, having internal facet 1060 opposing internal facet 1040 of movable bar 104, and top facet 1061; pair of adjustable parallel side walls 2100, 2100′, with expansion tabs 2101, 2101′ disposed between movable bar 104 and stationary bar 106; at least one hot gas blower 301 (303) coupled to external facet 1041 of movable bar 104, with slit 305 (306), disposed at the bottom of internal facet 1040 in communication with damper 3051 (3061), operable to selectably control opening of slit 305 (306) defined in (the bottom) movable bar 104, slit 305 being in fluid communication with at least one hot gas blower 301. Also illustrated are motors 3000, 3050, and 3030 configured to actuate various belts, operable to position and translate the at least one of: the PCB, the IC, the AP, the wafer, and an object comprising one or more of the foregoing 700 sought to be heated in the dispensing process along the dispensing process and along longitudinal axis X_{L100}.

Furthermore, adjustable quadrilateral frame 150 further comprises first powertrain comprised of actuators 1500, 1500′ and adjustment rails 107, 107′, in communication with stationary bar 106, operable to controllably position movable bar at a predetermined distance associated with predetermined dimension (for example width or length) of PCB, IC, wafer, or object 700 (see e.g., FIG. 6) comprising one or more of foregoing sought to undergo underfill process.

In yet another exemplary implementation, the PCB, IC, wafer, or object 700 comprising one or more of foregoing, is sought to undergo edge bonding. Edge bonding in the context of processing of printed circuit boards (PCBs) and surface-mounted technology involves applying high-adhesion adhesives along the periphery or corners of components such as Ball Grid Arrays (BGAs), Chip Scale Packages (CSPs), and other surface-mounted devices to enhance the mechanical reliability of these components, especially in applications that involve extensive temperature cycling or extreme shock and vibration.

The heating process is used in both the application and removal of edge bond adhesives. During the application process, the adhesive is typically dispensed at room temperature along the edges or corners of the component. The adhesive then undergoes a curing process, which often involves heat. The curing temperature and duration depend on the specific adhesive used, but it generally occurs at temperatures above the glass transition temperature (Tg) of the adhesive, with difference between the processing temperature and the Tg of the cured adhesive, configured to impart the desired viscosity on the adhesive (for example, using the Williams-Landel-Ferry equation).

Some edge bond adhesives are designed to be heat-curable, meaning they require elevated temperatures to fully cure and achieve their optimal mechanical properties. These temperatures can range from slightly above room temperature to well over 100° C., depending on the formulation. The heating process during curing serves to initiate and accelerate the chemical reactions within the adhesive, leading to the formation of strong bonds between the component and the PCB. Accordingly, in certain exemplary implementation, the heater used in the systems disclosed is operable to heat the components to temperature of between about 60° C. and 180° C., for example, between 140° C. and 160° C.

The term “engage” and various forms thereof, when used with reference to retention of a member (e.g., at least one of: PCB, IC, AP, wafer, and object comprising one or more of the foregoing 700 sought to be heated in the dispensing process), refer to the application of any forces that tend to hold two components together against inadvertent or undesired separating forces (e.g., such as may be introduced during use of either component). It is to be understood, however, that engagement does not require an interlocking connection in all cases, which is maintained against every conceivable type or magnitude of separating force. Also, “engaging element” or “engaging member” (e.g., slab 202) refers to one or a plurality of coupled components, at least one of which is configured for releasably engaging a tab or detent. For example, open quadrilateral frame 150 can be considered an engaging element.

In the context of the disclosure, the term “accommodate” refers to the ability of an accommodating element (e.g., adjustable open quadrilateral frame 150) to allow passage or retention of another element (e.g., at least one of: PCB, IC, AP, wafer, and object comprising one or more of the foregoing 700 sought to be heated in the dispensing process) at close tolerance, without substantial space for other elements or components. A skilled person would readily recognize, that while throughout the disclosure, shape descriptors are provided, for example, quadrilateral, still tetragonal, rectangle, trapezoid, other shapes and polygons are each likewise encompassed. So for example, an “open quadrilateral adjustable frame” can likewise be square, or for that matter, oval. Determination of the shape of each frame will be made based on overall constraints of the at least one of: PCB, IC, AP, wafer, and object comprising one or more of the foregoing 700 sought to be heated in the dispensing process.

Moreover, the term “actuator” refers to a device or assembly for imparting movement. The term actuator also refers generally to any of a number of actuation devices, which may be utilized in articulating various components in the assemblies described. For example, electromechanical linear actuators, pneumatic cylinders, hydraulic cylinders, and air bladders are all contemplated as being applicable to one or more of the exemplary implementations disclosed. Additionally, actuators may include other combinations of prime movers and links or members which may be utilized to actuate, move, transfer motion, articulate, lift, lower, rotate, pivot, extend, retract, or otherwise move links, linkages, platforms, stages, frames, carriages, sleds or any of the members of the assemblies discussed.

The terms “first,” “second,” and the like, when used herein do not denote any order, quantity, or importance, but are rather used to denote one element from another.

Furthermore, the term “operable”, in the context of the disclosure, means the system, assembly and/or the device and/or the program, or a certain element, component, or step is fully functional, sized, adapted and calibrated, comprises elements for, and meets applicable operability requirements to perform a recited function when activated, coupled, implemented, actuated, effected, realized, or when an executable program is executed by at least one processor associated with the system and/or the device. In relation to systems and circuits, the term “operable” means the system and/or the circuit is fully functional and calibrated, comprises logic for, having the hardware and firmware necessary, as well as the circuitry for, and meets applicable operability requirements to perform a recited function when executed by at least one processor.

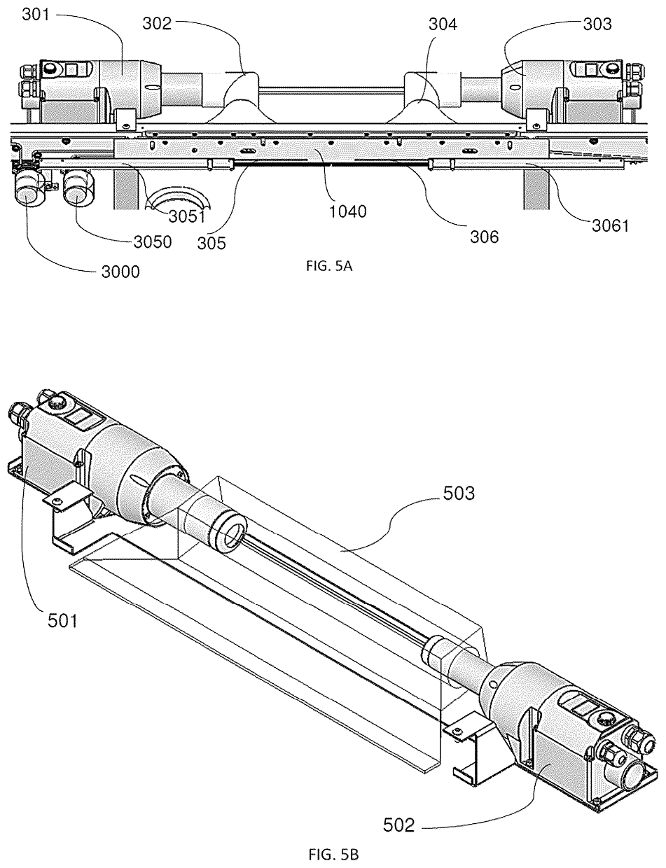

As further illustrated in FIGS. 2, 5, and 6, adjustable open quadrilateral frame 150 comprises pair of hot gas blowers 301, 303, which in an exemplary implementation, each having flared fitting 302, 304 coupled to corresponding slit 305, 306 defined in movable bar 104. Adjustable quadrilateral frame 150 further comprises actuators 3050, 3030, and 3000, configured to drive various belts (not shown), and translate the at least one of: the PCB, the IC, the AP, the wafer, and an object comprising one or more of the foregoing 700 sought to be heated in the dispensing process along longitudinal axis X_{L100}, while damper 3051, 3061, each operable to selectably control associated opening of associated slit 305, 306 defined in movable bar 104, and which can be adjusted manually (or using a dedicated actuator). Associated slit 305, 306 disposed at the bottom of movable bar 104 internal facet 1040, being in fluid communication with associated hot gas blower 301, 303 respectively. The gas can be, for example, air, nitrogen, argon or other noble gasses. Blower(s) 301 (303) can further be coupled to a heating element or heat exchangers used to heat the air to a predetermined temperature. FIG. 5B illustrates another exemplary implementation of the hot air blower assembly, where two blowers 501, 502 blow hot gas (e.g., air, nitrogen) into manifold 503, being in liquid communication with open chamber formed of adjustable quadrilateral frame 150, the PCB, the IC, the AP, the wafer, and an object comprising one or more of the foregoing 700 forming the lid of closed quadrilateral chamber 160 (see e.g., FIG. 6), and vertically adjustable platform 200, with slab 202 forming the floor of closed quadrilateral chamber 160.

As further illustrated (see e.g., FIG. 6) slab 202 can be configured to further comprise at least one support member 2025i, the at least one support member configured to support: PCB, IC, AP, wafer, or object 700 (see e.g., FIG. 6) comprising one or more of foregoing sought to undergo heating process. The location and size of (at least one) support member 2025i will depend on the topology of PCB, IC, wafer, or object 700 (see e.g., FIG. 6) comprising one or more of foregoing sought to undergo dispensing process, or the sensitivity of certain components and IC's coupled to the underside of the PCB, the IC, the AP, the wafer, and an object comprising one or more of the foregoing 700, as will the clearance requirement between slit(s) 305 (306) and underside of at least one of: PCB, IC, AP, wafer, and object comprising one or more of the foregoing 700 sought to be heated in the dispensing process, and vertically adjustable platform 200, with slab 202 forming the chamber floor. As illustrated further in FIGS. 3B-3D, movement of vertically adjustable platform 200 in the Z-direction (in other words, vertical translation), positioning of stationary bar 106 relative to movable bar 104, and locating adjustable side walls 2100, 2100′, will create custom hot gas (e.g., air) bath for PCB, IC, wafer, or object 700 (see e.g., FIG. 6) comprising one or more of foregoing sought to undergo underfill process, by soaking the part in the adjustable volume formed by lid, floor and adjustable frame to ensure uniform and rapid heating, while maintaining the necessary clearance from the slits (where the gas temperature is the hottest), thereby potentially compensating for any component sensitivity.

The assemblies and methods for treating PCB, IC, wafer, or object 700 (see e.g., FIG. 6) comprising one or more of foregoing sought to undergo underfill process described herein, can further be in electric communication with at least one sensor (e.g., temperature sensor, IR sensor, thermocouple, thermistor, pyrometer) and a processor, configured to maintain a predetermined temperature or a programmable temperature profile throughout the preheating process and the recycling process and additionally or alternatively, diagnose problems in the system. For example, the system can comprise sensor 170 array at various locations (for example, on support member 2025i), or on stage 100 with temperature and/or temperature and/or anemometer data feedback to the processor, which, in turn, will control the various valves, affecting hot gas flow temperature, hot gas flowrate, and the like to the adjustable closed chamber.

Accordingly and in yet another exemplary implementation, assemblies 10 disclosed herein further comprising central processing assembly (CPM) 800, in communication with motor 210 of vertically adjustable platform 200, first actuator 3050, second actuator 3000, first powertrain 1500, and sensor 170, CPM 800 further comprising at least one processor in communication with non-transitory memory device storing thereon computer-readable media with set of executable instructions, configured when executed to cause at least one processor, in response to user 801 input to: based on dimensions of the at least one of: the PCB, the IC, the AP, the wafer, and the object comprising one or more of the foregoing 700 sought to be heated in the dispensing process, coupled to assembly 10, adjust dimensions of adjustable quadrilateral frame 150; using vertically adjustable platform 200, adjust dimension of closed quadrilateral chamber 160; adjust damper 3051 (3061); operate hot gas blower 301; and using sensor 170, continuously monitor temperature of the at least one of: the PCB, the IC, the AP, the wafer, and an object comprising one or more of the foregoing 700 sought to be heated in the dispensing process-coupled to assembly 10.

In an exemplary implementation, the assemblies disclosed, are used to implement the methods provided. Accordingly, provided herein is a method of heating at least one of: a printed circuit boards (PCBs), an integrated circuits (ICs), an advanced packaging (AP), a wafer, and an object comprising one or more of the foregoing sought to be heated in a dispensing process, the method implemented in an assembly comprising: a stage defining a longitudinal axis; a vertically adjustable platform coupled to the stage; and an adjustable quadrilateral frame, in fluid communication with at least one hot gas blower, the adjustable quadrilateral frame operable for selectably adjusting the dimensions of a closed quadrilateral chamber formed by the adjustable quadrilateral frame, the PCB, IC, AP, wafer, and the object comprising one or more of the foregoing 700 sought to be heated in the dispensing process (the lid of the chamber) and a slab coupled to the vertically adjustable platform (the floor of the closed chamber, the method comprising: based on the length and width of the at least one of: the PCB, the IC, the AP, the wafer, and an object comprising one or more of the foregoing sought to be heated in a dispensing process-adjusting the dimensions of the adjustable open quadrilateral frame; based on at least one of: a thickness, topology, and a clearance requirement of the at least one of: the PCB, the IC, the AP, the wafer, and an object comprising one or more of the foregoing, each sought to be heated in a dispensing process, and using the vertically adjustable platform, raising the at least one of: the PCB, the IC, the AP, the wafer, and an object comprising one or more of the foregoing sought to be heated in a dispensing process to the assembly forming a lid to the closed quadrilateral chamber; actuating the hot gas blower; and using a sensor included with the assembly, continuously monitoring the temperature of the object coupled to the assembly for a predetermined time at a predetermined temperature range, for example between 60° C. and 100° C., or between 80° C. and 90° C. It is noted, that in order for the object to reach the temperature range disclosed, the heater is configured to operate at higher temperatures, for example up to about 160° C.

The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the channel(s) includes one or more channel). Reference throughout the specification to “one exemplary implementation”, “another exemplary implementation”, “an exemplary implementation”, and so forth, means that a particular element (e.g., feature, structure, and/or characteristic) described in connection with the exemplary implementation is included in at least one exemplary implementation described herein, and may or may not be present in other exemplary implementations. In addition, it is to be understood that the described elements may be combined in any suitable manner in the various exemplary implementations.

In addition, for the purposes of the present disclosure, directional or positional terms such as “top”, “apical”, “basal”, “proximal”, “distal”, “bottom”, “upper,” “lower,” “side,” “front,” “frontal,” “forward,” “rear,” “rearward,” “back,” “trailing,” “above,” “below,” “left,” “right,” “radial ,” “vertical,” “upward,” “downward,” “outer,” “inner,” “exterior,” “interior,” “intermediate,” etc., are merely used for convenience in describing the various exemplary implementations of the present disclosure.

The term “coupled”, including its various forms such as “operably coupled”, “coupling” or “coupleable”, refers to and comprises any direct or indirect, structural coupling, connection or attachment, or adaptation or capability for such a direct or indirect structural or operational coupling, connection or attachment, including integrally formed components and components which are coupled via or through another component or by the forming process (e.g., an electromagnetic field). Indirect coupling may involve coupling through an intermediary member or adhesive, or abutting and otherwise resting against, whether frictionally (e.g., against a wall) or by separate means without any physical connection.

The processor can further have a memory assembly with computer readable media stored thereon, comprising a set of instructions thereon configured to carry out the preheating (or heating) methods described herein, provide temperature flowrate controls, timing, movement, vacuum flow, and form continuous monitoring of the process.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly, and in an exemplary implementation, provided herein is an assembly for heating an object: a stage defining a longitudinal axis; a vertically adjustable platform coupled to the stage; and an adjustable quadrilateral frame, in fluid communication with at least one hot gas blower, the adjustable quadrilateral frame operable for selectably adjusting the dimensions of a closed quadrilateral chamber formed by the quadrilateral open frame, the object forming a lid and a slab coupled to the vertically adjustable platform forming a floor, wherein (i) the object is: a printed circuit boards (PCBs), an integrated circuits (ICs), an advanced packaging (AP), a wafer, or an electronic component comprising one or more of the foregoing sought to be heated in a dispensing process, wherein (ii) the vertically adjustable platform comprises: a base plate having a top surface a motor, coupled to the top surface of the base plate; and a drivetrain operably coupled to the motor, or to an actuator wherein the drivetrain is further coupled to the slab, the drivetrain operable to selectably raise and lower the slab, (iii) the adjustable quadrilateral frame comprises: a stationary bar having an internal facet, and external facet and a top facet, disposed transverse to the longitudinal axis defined by the stage; a movable bar in parallel with the stationary bar, having an internal facet opposing the internal facet of the stationary bar, and a top facet; a pair of adjustable parallel side walls, disposed between the stationary bar and the movable bar; the at least one hot gas blower coupled to the external facet of the stationary bar; a damper, operable to selectably control an opening of a slit defined in the movable bar, the slit being in fluid communication with the at least one hot gas blower; and the at least one hot gas blower, (iv) the adjustable quadrilateral frame further comprises a first powertrain, in communication with the movable bar, operable to controllably position the movable bar at a distance associated with a predetermined dimension of the object, wherein (v) the adjustable quadrilateral frame comprises a pair of hot gas blowers, each hot gas blower being in communication with an associated damper, operable to selectably control an associated opening of an associated slit defined in the movable bar, the associated slit being in fluid communication with an associated hot gas blower, (vi) the slab further comprises at least one support member, the at least one support member configured to support the object, the assembly further (vii) comprising at least one sensor, operable to sense the temperature of an object operably coupled to the assembly and (viii) further comprising a central processing assembly (CPM), in communication with the motor, or the actuator of the vertically adjustable platform, the first actuator, the second actuator, the first power, and the sensor, the CPM further comprising at least one processor in communication with a non-transitory memory device storing thereon a computer-readable media with a set of executable instructions, configured when executed to cause the at least one processor, in response to user input to: based on the dimensions of the object coupled to the assembly, adjust the dimensions of the adjustable quadrilateral frame; using the vertically adjustable platform, adjust the dimension of the closed quadrilateral chamber; adjust the damper; operate the hot gas blower; and using the sensor, continuously monitor the temperature of the object coupled to the assembly.

In another exemplary implementation, provided herein is a method of heating an object sought to be heated in a dispensing process, the method implemented in an assembly comprising: a stage defining a longitudinal axis; a vertically adjustable platform coupled to the stage; and an adjustable quadrilateral frame, in fluid communication with at least one hot gas blower, the adjustable quadrilateral frame operable for selectably adjusting the dimensions of a closed quadrilateral chamber formed by the adjustable quadrilateral frame, the object forming a lid of the chamber, and a slab coupled to the vertically adjustable platform forming the floor of the closed quadrilateral chamber, the method comprising: based on the length and width of the object-adjusting the dimensions of the adjustable open quadrilateral frame; based on at least one of: a thickness, topology, and a clearance requirement of the object sought to be heated in a dispensing process, and using the vertically adjustable platform, raising the object through the open quadrilateral frame forming a lid to the closed quadrilateral chamber; actuating the hot gas blower; and using a sensor included with the assembly; and continuously monitoring the temperature of the object for a predetermined time at a predetermined temperature range, wherein (ix) the object is: a printed circuit board (PCB), an integrated circuit (IC), an advanced packaging (AP), a wafer, or an electronic component comprising one or more of the foregoing, each sought to be heated in a dispensing process, wherein (x) the temperature range is between about 60° C. and about 100° C., with the heater being operable for heating to temperatures between 60 ° and 180° C., for example, between 60° C. and 160° C., wherein (xi) the vertically adjustable platform comprises: a base plate having a top surface a motor, coupled to the top surface of the base plate; and a drivetrain operably coupled to the motor, wherein the drivetrain is further coupled to the slab, the drivetrain operable to selectably (in other words, without affecting any other operational parameters) raise and lower the slab, (xii) the adjustable quadrilateral frame comprises: a movable bar having an internal facet, and external facet and a top facet, disposed transverse to the longitudinal axis defined by the stage; a stationary bar in parallel with the movable bar, having an internal facet opposing the internal facet of the movable bar, and a top facet; a pair of adjustable parallel side walls, disposed between the movable bar and the stationary bar; the at least one hot gas blower coupled to the external facet of the movable bar; a first actuator in communication with a damper, operable to selectably control an opening of a slit defined in the movable bar, the slit being in fluid communication with the at least one hot gas blower; and a second actuator, in communication with the at least one hot gas blower, wherein (xiii) the adjustable quadrilateral frame further comprises a first powertrain, in communication with the stationary bar, operable to controllably position the movable bar at a distance associated with a predetermined dimension the at least one of: the PCB, the IC, the AP, the wafer, and an object comprising one or more of the foregoing sought to be heated in a dispensing process, wherein (xiv) the adjustable quadrilateral frame comprises a pair of hot gas blowers, the adjustable quadrilateral frame further comprises an actuator for each hot gas blower, each actuator being in communication with an associated damper, operable to selectably control an associated opening of an associated slit defined in the movable bar, the associated slit being in fluid communication with an associated hot gas blower, (xv) the slab further comprises at least one support member, the at least one support member configured to support the at least one of: the PCB, the IC, the AP, the wafer, and an object comprising one or more of the foregoing sought to be heated in a dispensing process, further (xvi) comprising a central processing module (CPM), in communication with the motor of the vertically adjustable platform, the first actuator, the second actuator, the first powertrain, and the sensor, the CPM further comprising at least one processor in communication with a non-transitory memory device storing thereon a computer-readable media with a set of executable instructions, configured when executed to cause the at least one processor, in response to user input, to perform the steps of adjusting the dimensions of the adjustable open quadrilateral frame; based on at least one of: a thickness, topology, and a clearance requirement of the object sought to be heated in a dispensing process, and using the vertically adjustable platform, raising the object through the open quadrilateral frame forming a lid to the closed quadrilateral chamber; actuating the hot gas blower; and using a sensor included with the assembly, continuously monitoring the temperature of the object for a predetermined time at a predetermined temperature range, wherein (xvii) the dispensing process is an underfill process, (xviii) a package stacking process, (xix) an edge bonding process, or (xx) similar dispensing process.

While in the foregoing specification the assemblies and methods for heating the at least one of: the PCB, the IC, the AP, the wafer, and an object comprising one or more of the foregoing sought to be heated in a dispensing process, have been described in relation to certain preferred exemplary implementations, and many details are set forth for purpose of illustration, it will be apparent to those skilled in the art that the disclosure is susceptible to additional exemplary implementations and that certain of the details described in this specification and as are more fully delineated and defined in the following claims, can be varied considerably without departing from the basic principles of this disclosure.

1. (canceled)

2. An assembly for heating an object, the assembly comprising:
a) a stage defining a longitudinal axis;
b) a vertically adjustable platform coupled to the stage; and
c) an adjustable quadrilateral frame, in fluid communication with at least one hot gas blower, the adjustable quadrilateral frame operable for selectably adjusting the dimensions of a closed quadrilateral chamber formed by the quadrilateral open frame, the object forming a lid and a slab coupled to the vertically adjustable platform forming a floor, wherein the object is: a printed circuit boards (PCBs), an integrated circuits (ICs), an advanced packaging (AP), a wafer, or an electronic component comprising one or more of the foregoing sought to be heated in a dispensing process.

3. An assembly for heating an object, the assembly comprising:
a) a stage defining a longitudinal axis;
b) a vertically adjustable platform coupled to the stage; and
c) an adjustable quadrilateral frame, in fluid communication with at least one hot gas blower, the adjustable quadrilateral frame operable for selectably adjusting the dimensions of a closed quadrilateral chamber formed by the quadrilateral open frame, the object forming a lid and a slab coupled to the vertically adjustable platform forming a floor, wherein the vertically adjustable platform comprises:
d) a base plate having a top surface
e) a motor, coupled to the top surface of the base plate; and
f) a drivetrain operably coupled to the motor, or to an actuator wherein the drivetrain is further coupled to the slab, the drivetrain operable to selectably raise and lower the slab.

4. The assembly of claim 3, wherein the adjustable quadrilateral frame comprises:
a) a stationary bar having an internal facet, and external facet and a top facet, disposed transverse to the longitudinal axis defined by the stage;
b) a movable bar in parallel with the stationary bar, having an internal facet opposing the internal facet of the stationary bar, and a top facet;
c) a pair of adjustable parallel side walls, disposed between the stationary bar and the movable bar;
d) the at least one hot gas blower coupled to the external facet of the stationary bar;
e) a damper, operable to selectably control an opening of a slit defined in the movable bar, the slit being in fluid communication with the at least one hot gas blower; and
f) the at least one hot gas blower.

5. The assembly of claim 3, wherein the adjustable quadrilateral frame further comprises a first powertrain, in communication with the movable bar, operable to controllably position the movable bar at a distance associated with a predetermined dimension of the object.

6. The assembly of claim 4, wherein the adjustable quadrilateral frame comprises a pair of hot gas blowers, each hot gas blower being in communication with an associated damper, operable to selectably control an associated opening of an associated slit defined in the movable bar, the associated slit being in fluid communication with an associated hot gas blower.

7. The assembly of claim 4, wherein the slab further comprises at least one support member, the at least one support member configured to support the object.

8. The assembly of claim 5, further comprising at least one sensor, operable to sense the temperature of an object operably coupled to the assembly.

9. The assembly of claim 8, further comprising a central processing assembly (CPM), in communication with the motor, or the actuator of the vertically adjustable platform, the first actuator, the second actuator, the first power, and the sensor, the CPM further comprising at least one processor in communication with a non-transitory memory device storing thereon a computer-readable media with a set of executable instructions, configured when executed to cause the at least one processor, in response to user input to:
a) based on the dimensions of the object coupled to the assembly, adjust the dimensions of the adjustable quadrilateral frame;
b) using the vertically adjustable platform, adjust the dimension of the closed quadrilateral chamber;
c) adjust the damper;
d) operate the hot gas blower; and
e) using the sensor, continuously monitor the temperature of the object coupled to the assembly.

10. A method of heating an object sought to be heated in a dispensing process, the method implemented in an assembly comprising: a stage defining a longitudinal axis; a vertically adjustable platform coupled to the stage; and an adjustable quadrilateral frame, in fluid communication with at least one hot gas blower, the adjustable quadrilateral frame operable for selectably adjusting the dimensions of a closed quadrilateral chamber formed by the adjustable quadrilateral frame, the object forming a lid of the chamber, and a slab coupled to the vertically adjustable platform forming the floor of the closed quadrilateral chamber, the method comprising:
a) based on the length and width of the object-adjusting the dimensions of the adjustable open quadrilateral frame;
b) based on at least one of: a thickness, topology, and a clearance requirement of the object sought to be heated in a dispensing process, and using the vertically adjustable platform, raising the object through the open quadrilateral frame forming a lid to the closed quadrilateral chamber;
c) actuating the hot gas blower; and
d) using a sensor included with the assembly, continuously monitoring the temperature of the object for a predetermined time at a predetermined temperature range.

11. The method of claim 10, wherein the object is: a printed circuit board (PCB), an integrated circuit (IC), an advanced packaging (AP), a wafer, or an electronic component comprising one or more of the foregoing, each sought to be heated in a dispensing process.

12. The method of claim 10, wherein the temperature range is between about 60° C. and about 100° C.

13. The method of claim 10, wherein the vertically adjustable platform comprises:
a) a base plate having a top surface
b) a motor, coupled to the top surface of the base plate; and
c) a drivetrain operably coupled to the motor, wherein the drivetrain is further coupled to the slab, the drivetrain operable to selectably raise and lower the slab.

14. The method of claim 13, wherein the adjustable quadrilateral frame comprises:
a) a movable bar having an internal facet, and external facet and a top facet, disposed transverse to the longitudinal axis defined by the stage;
b) a stationary bar in parallel with the movable bar, having an internal facet opposing the internal facet of the movable bar, and a top facet;
c) a pair of adjustable parallel side walls, disposed between the movable bar and the stationary bar;
d) the at least one hot gas blower coupled to the external facet of the movable bar;
e) a first actuator in communication with a damper, operable to selectably control an opening of a slit defined in the movable bar, the slit being in fluid communication with the at least one hot gas blower; and
f) a second actuator, in communication with the at least one hot gas blower.

15. The method of claim 14, wherein the adjustable quadrilateral frame further comprises a first powertrain, in communication with the stationary bar, operable to controllably position the movable bar at a distance associated with a predetermined dimension the at least one of: the PCB, the IC, the AP, the wafer, and an object comprising one or more of the foregoing sought to be heated in a dispensing process.

16. The method of claim 14, wherein the adjustable quadrilateral frame comprises a pair of hot gas blowers, the adjustable quadrilateral frame further comprises an actuator for each hot gas blower, each actuator being in communication with an associated damper, operable to selectably control an associated opening of an associated slit defined in the movable bar, the associated slit being in fluid communication with an associated hot gas blower.

17. The method of claim 14, wherein the slab further comprises at least one support member, the at least one support member configured to support the at least one of: the PCB, the IC, the AP, the wafer, and an object comprising one or more of the foregoing sought to be heated in a dispensing process.

18. The method of claim 15, further comprising a central processing module (CPM), in communication with the motor of the vertically adjustable platform, the first actuator, the second actuator, the first powertrain, and the sensor, the CPM further comprising at least one processor in communication with a non-transitory memory device storing thereon a computer-readable media with a set of executable instructions, configured when executed to cause the at least one processor, in response to user input, to perform the steps of claim 10.

19. The method of claim 11, wherein the dispensing process is an underfill process.

20. The method of claim 11, wherein the dispensing process is a package stacking process.

21. The method of claim 11, wherein the dispensing process is an edge bonding process.
